(19) United States
(12) Patent Application Publication
(10) Pub. No.: US 2021/0134613 A1
(43) Pub. Date: May 6, 2021

(54) CHIP CARRYING STRUCTURE HAVING CHIP-SUCTION FUNCTION

(71) Applicant: ASTI GLOBAL INC., TAIWAN, Taichung City (TW)

(72) Inventors: CHIEN-SHOU LIAO, New Taipei City (TW); CHUN-AN LU, Pingtung County (TW)

(21) Appl. No.: 16/924,486

(22) Filed: Jul. 9, 2020

(30) Foreign Application Priority Data
Nov. 4, 2019 (TW) 108139915

(51) Int. Cl. H01L 21/673; H01L 21/683; H01L 21/67; B23K 1/005

(52) U.S. Cl. CPC H01L 21/673; B23K 1/0056; H01L 21/67115; H01L 21/683

(57) ABSTRACT

A chip carrying structure having chip-suction function is provided. The chip carrying structure includes a non-circuit substrate and a plurality of micro heaters. The non-circuit substrate has a plurality of openings and a plurality of air extraction channels respectively communicated with the openings. The micro heaters are disposed on the non-circuit substrate and carried by the non-circuit substrate. Each of the openings of the non-circuit substrate contacts and suctions one of a plurality of chips, and no adhesive layer is disposed between the non-circuit substrate and the chip. When air is exhausted from the air extraction channels, the openings of the non-circuit substrate can be used to respectively suck the chips, so that the chips can be attached to the non-circuit substrate, and the micro heater can heat a solder ball that is contacted by the chip.

### CROSS-REFERENCE TO RELATED PATENT APPLICATION

This application claims the benefit of priority to Taiwan Patent Application No. 108139915, filed on Nov. 4, 2019. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a chip carrying structure, and more particularly to a chip carrying structure having chip-suction function.

### BACKGROUND OF THE DISCLOSURE

In recent years, with the rapid development of electronic and semiconductor technologies, electronic products have been continuously modernized, and are designed to be light, thin, short, and small. Circuit boards are widely used in various electronic devices. The circuit board usually has a plurality of solder pads disposed on the surface thereof. In the process, solders are respectively arranged on the solder pads of the circuit board, and then various electronic components are mounted onto the circuit board by a reflow process, such that the electronic components are electrically connected with each other through circuit layers in the circuit board.

### SUMMARY OF THE DISCLOSURE

In response to the above-referenced technical inadequacies, the present disclosure provides a chip carrying structure having chip-suction function.

In one aspect, the present disclosure provides a chip carrying structure having chip-suction function, including: a non-circuit substrate and a plurality of micro heaters. The non-circuit substrate has a plurality of openings and a plurality of air extraction channels respectively communicated with the openings. The micro heaters are disposed on the non-circuit substrate and carried by the non-circuit substrate. Each of the openings of the non-circuit substrate contacts and suctions one of a plurality of chips, and no adhesive layer is disposed between the non-circuit substrate and the chip.

In certain embodiments, the non-circuit substrate is a single substrate or a composite substrate, the chips are correspondingly disposed under the micro heaters, and the chip is an IC chip or an LED chip; wherein each of the micro heaters heats at least one of the chips so as to bond the at least one chip on a circuit substrate through a solder ball.

In certain embodiments, the non-circuit substrate includes a first substrate and a second substrate connected with the first substrate, the hardness of the first substrate is greater than, equal to or smaller than the hardness of the second substrate, the openings are formed on the first substrate, and each of the air extraction channels passes through the first substrate and the second substrate; wherein the first substrate has a surrounding convex portion disposed on an outer surface thereof for contacting the chip, and the air extraction channels are communicated with each other.

In certain embodiments, the non-circuit substrate has a surrounding convex portion disposed on an outer surface thereof for contacting the chip, and the air extraction channels are communicated with each other.

In another aspect, the present disclosure provides a chip carrying structure having chip-suction function, including a non-circuit substrate for carrying at least one chip, and at least one micro heater carried by the non-circuit substrate for heating at least one solder ball that is contacted by the at least one chip. The non-circuit substrate has a plurality of openings and a plurality of air extraction channels respectively communicated with the openings.

In certain embodiments, the at least one chip is bonded on a circuit substrate through the at least one solder ball, so that the at least one chip is attached and carried by the circuit substrate to be separate from the non-circuit substrate.

In certain embodiments, the non-circuit substrate is a single substrate or a composite substrate, the at least one chip is correspondingly disposed under the at least one micro heater, and the at least one chip is an IC chip or an LED chip; wherein the at least one micro heater heats the at least one chip so as to bond the at least one chip on a circuit substrate through the at least one solder ball.

In certain embodiments, the non-circuit substrate includes a first substrate and a second substrate connected with the first substrate, the hardness of the first substrate is greater than, equal to or smaller than the hardness of the second substrate, the openings are formed on the first substrate, and each of the air extraction channels passes through the first substrate and the second substrate; wherein the first substrate has a surrounding convex portion disposed on an outer surface thereof for contacting the at least one chip, and the air extraction channels are communicated with each other.

In certain embodiments, the non-circuit substrate has a surrounding convex portion disposed on an outer surface thereof for contacting the at least one chip, and the air extraction channels are communicated with each other.

In certain embodiments, the chip carrying structure further includes a laser heating module disposed above the non-circuit substrate for projecting a laser light beam onto the at least one solder ball.

Therefore, by virtue of “the non-circuit substrate having a plurality of openings and a plurality of air extraction channels respectively communicated with the openings” and “the micro heater being carried by the non-circuit substrate”, each of the openings of the non-circuit substrate can contact and suck a chip, and the micro heater can heat at least one solder ball that is contacted by the at least one chip.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a schematic view of a chip carrying structure having chip-suction function prior to contact with a plurality of solder balls according to a first embodiment of the present disclosure.

FIG. 2 is a schematic view of the chip carrying structure having chip-suction function after coming in contact with the solder balls according to a first embodiment of the present disclosure.

FIG. 3 is a schematic view of a plurality of chips being bonded on a circuit substrate through the solder balls.

FIG. 4 is a schematic view of a chip carrying structure having chip-suction function according to a second embodiment of the present disclosure.

FIG. 5 is a schematic view of a chip carrying structure having chip-suction function according to a third embodiment of the present disclosure.

FIG. 6 is a schematic view of a chip carrying structure having chip-suction function according to a fourth embodiment of the present disclosure.

FIG. 7 is a schematic view of a chip carrying structure having chip-suction function according to a fifth embodiment of the present disclosure.

FIG. 8 is a schematic view of a chip carrying structure having chip-suction function according to a sixth embodiment of the present disclosure.

FIG. 9 is a schematic view of a chip carrying structure having chip-suction function according to a seventh embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

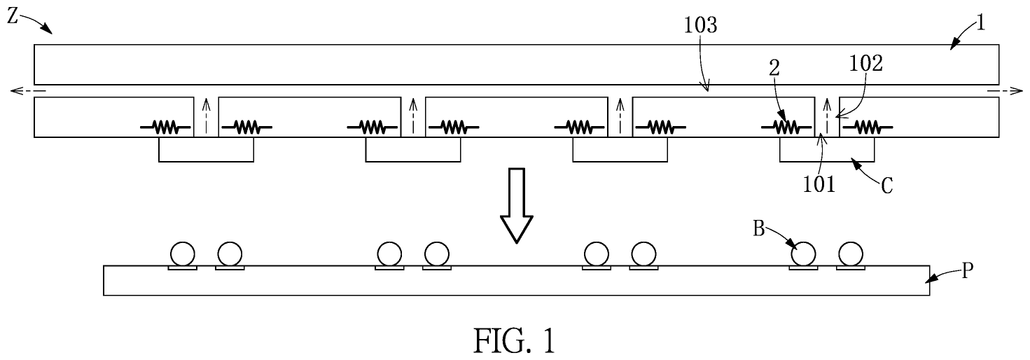

Referring to FIG. 1 to FIG. 9, the present disclosure provides a chip carrying structure Z having chip-suction function, including a non-circuit substrate 1 and at least one micro heater 2. More particularly, the non-circuit substrate is capable of carrying at least one chip C, and the non-circuit substrate 1 has a plurality of openings 101 and a plurality of air extraction channels 102 respectively communicated with the openings 101. The at least one micro heater 2 can be carried by the non-circuit substrate 1 for heating at least one solder ball B that is contacted by the at least one chip C. In addition, the at least one chip C can be correspondingly disposed on any position under the at least one micro heater 2, and the at least one chip C is proximate to the at least one micro heater 2. Therefore, when the at least one chip C contacts the at least one solder ball B, the at least one micro heater 2 can heat the at least one chip C and the at least one solder ball B, so that the at least one chip C can be bonded on a circuit substrate P through the at least one solder ball B, and the at least one chip C can be attached and carried by the circuit substrate P to be separate from the non-circuit substrate 1. That is to say, a heat source generated by the at least one micro heater 2 can be transmitted to the at least one solder ball B through the at least one chip C, so that the at least one chip C can be bonded on the circuit substrate P through the at least one solder ball B, and the at least one chip C does not need to be carried by the non-circuit substrate 1.

### First Embodiment

Referring to FIG. 1 to FIG. 3, a first embodiment of the present disclosure provides a chip carrying structure Z having chip-suction function (or chip-absorbing function), including a non-circuit substrate 1 and at least one micro heater 2.

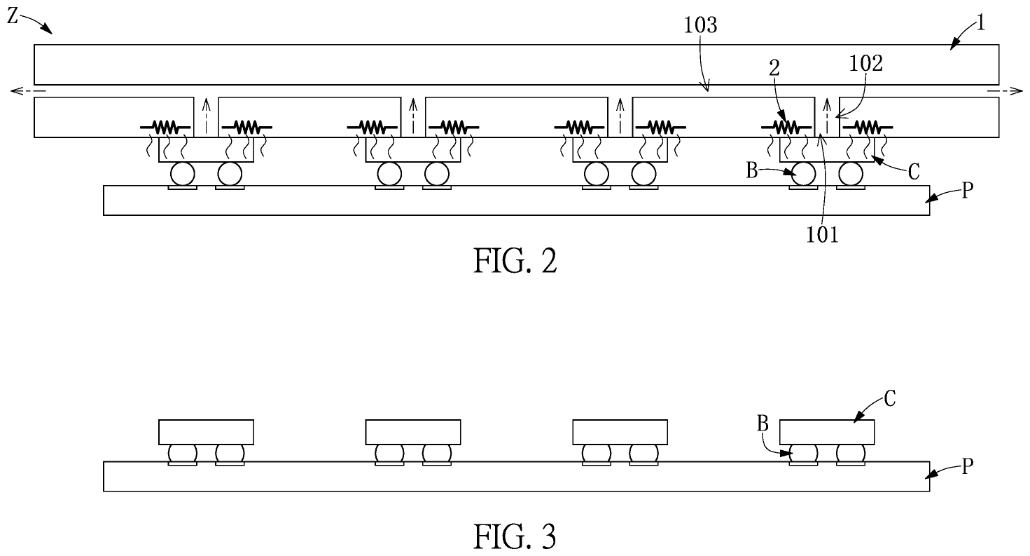

Firstly, as shown in FIG. 1, the non-circuit substrate 1 has a plurality of openings 101 and a plurality of air extraction channels 102 respectively communicated with the openings 101, and the air extraction channels 102 can be communicated with each other. Therefore, when air is exhausted from a communication channel 103 that is communicated with the air extraction channels 102 (shown as the arrows in FIG. 1 or FIG. 2), each of the openings 101 of the non-circuit substrate 1 can contact and suck a corresponding chip C, so that the chips C can be correspondingly arranged under the micro heaters 2. It should be noted that no any adhesive layer is disposed between the non-circuit substrate 1 and the chip C, so that the non-circuit substrate 1 is capable of capturing the chips C without an extra adhesive layer. That is to say, when air is exhausted from the communication channel 103, the opening 101 of the non-circuit substrate 1 can be used to respectively suck the chips C, so that the chips C can be attached to the non-circuit substrate 1 without any adhesive layer.

For example, the non-circuit substrate 1 may be a single substrate or a composite substrate. In addition, the non-circuit substrate 1 may be made of glass, quartz, sapphire, ceramic, or may be a silicon wafer; or the non-circuit substrate 1 may be a polydimethylsiloxane (PDMS) substrate, also known as dimethylpolysiloxane or dimethicone, belonging to a group of polymeric organosilicon compounds that are commonly referred to as silicones. PDMS is the most widely used silicon-based organic polymer, and is particularly known for its unusual rheological (or flow) properties. PDMS is optically clear, and, in general, inert, non-toxic, and non-flammable. Furthermore, PDMS is viscoelastic, meaning that at long flow times (or high temperatures), it acts like a viscous liquid, similar to honey. However, at short flow times (or low temperatures), it acts like an elastic solid, similar to rubber. Viscoelasticity is a form of nonlinear elasticity that is common amongst noncrystalline polymers. The loading and unloading of a stress-strain curve for PDMS do not coincide; rather, the amount of stress will vary based on the degree of strain, and the general rule is that increasing strain will result in greater stiffness. When the load itself is removed, the strain is slowly recovered (rather than instantaneously). This time-dependent elastic deformation results from the long-chains of the polymer. However, the aforementioned description for the non-circuit substrate 1 of the first embodiment is merely an example and is not meant to limit the scope of the present disclosure.

For example, the chip C may be an IC (integrated circuit) chip, an LED (light-emitting diode) chip, any type of semiconductor chip, or any type of electronic chip. In addition, the chip C may be a micro LED including an n-type conductive layer, a light-emitting layer traversable by a laser source, and a p-type conductive layer that are stacked on top of one another. The n-type conductive layer may be an n-type gallium nitride material layer or an n-type gallium arsenide material layer, the light-emitting layer may be a multi-quantum well structure layer, and the p-type conductive layer may be a p-type gallium nitride material layer or a p-type gallium arsenide material layer. Moreover, the chip C may also be a mini LED including a base layer, an n-type conductive layer, a light-emitting layer traversable by a laser source, and a p-type conductive layer that are stacked on top of one another. The base layer may be a sapphire material layer, the n-type conductive layer may be an n-type gallium nitride material layer or an n-type gallium arsenide material layer, the light-emitting layer may be a multi-quantum well structure layer, and the p-type conductive layer may be a p-type gallium nitride material layer or a p-type gallium arsenide material layer. The base layer may also be a quartz base layer, a glass base layer, a tantalum base layer or a base layer of any material. However, the aforementioned description for the chip C of the first embodiment is merely an example and is not meant to limit the scope of the present disclosure.

Furthermore, referring to FIG. 1 and FIG. 2, the micro heaters 2 are disposed on the non-circuit substrate 1 and carried by the non-circuit substrate 1, and the solder balls B can be arranged on a circuit substrate P in advance. When each of the micro heaters 2 heats at least one of the chips C, the at least one chip C can be bonded on the circuit substrate P through the solder ball B that receives heat from the at least one of the chips C. When the chip C is bonded on the circuit substrate P through the solder ball B, the chip C does not need to be carried by the non-circuit substrate 1, so that the chip C can be separated from the non-circuit substrate 1 after bonding the chip C on the circuit substrate P. For example, the micro heaters 2 can be arranged in series or in parallel, and electrically connected to a power supply, and the micro heater 2 can be disposed on the surface of the non-circuit substrate 1 or embedded in the non-circuit substrate 1. For example, when each chip C is disposed on the two corresponding solder balls B, each of the micro heaters 2 can be driven to heat the corresponding chip C, and each solder ball B can be indirectly heated and gradually softened due to the heat source that is transmitted from the corresponding chip C. After each solder ball B is hardened, each chip C can be firmly positioned on and electrically connected to the circuit substrate P through the corresponding solder balls B (as shown in FIG. 3). It should be noted that the non-circuit substrate 1 of the present disclosure may be provided with a feedback circuit unit which is mainly composed of a driving circuit, a signal reading circuit and a temperature control circuit, for controlling the heating temperature of the micro heater 2. However, the aforementioned description for the micro heater 2 of the first embodiment is merely an example and is not meant to limit the scope of the present disclosure.

### Second Embodiment

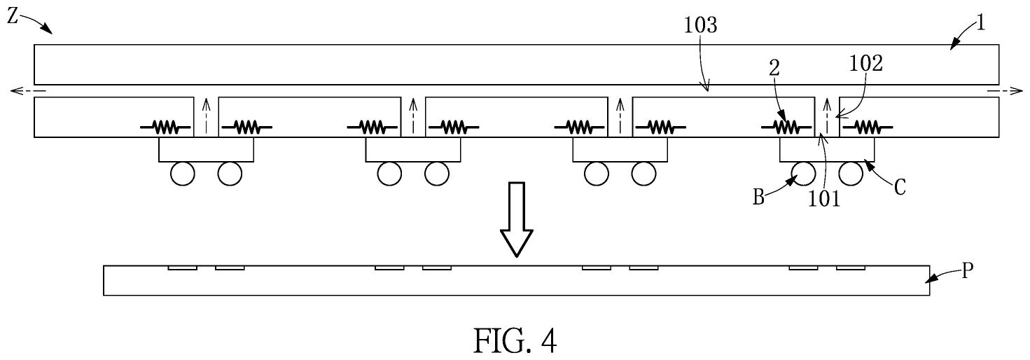

Referring to FIG. 4, a second embodiment of the present disclosure provides a chip carrying structure Z having chip-suction function, including a non-circuit substrate 1 and at least one micro heater 2. Comparing FIG. 4 with FIG. 1, the difference between the second embodiment and the first embodiment is as follows: the solder balls B are arranged on the circuit substrate P in advance as shown in the first embodiment (as shown in FIG. 1), and the solder balls B are arranged on the bottom side of the chip C in advance as shown in the second embodiment (as shown in FIG. 4). That is to say, the solder balls B can be respectively arranged on the pads of the circuit substrate P in advance (such as in the first embodiment as shown in FIG. 1) or at least two solder balls B can be arranged on the bottom side of the corresponding chip C in advance (such as in the second embodiment as shown in FIG. 4). However, the aforementioned description of the second embodiment is merely an example and is not meant to limit the scope of the present disclosure.

### Third Embodiment

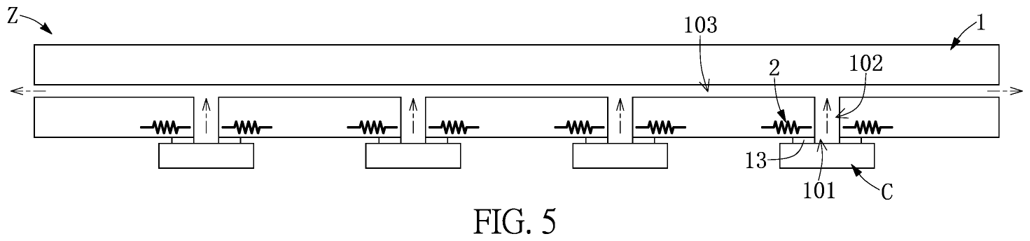

Referring to FIG. 5, a third embodiment of the present disclosure provides a chip carrying structure Z having chip-suction function, including a non-circuit substrate 1 and at least one micro heater 2. Comparing FIG. 5 with FIG. 1, the difference between the third embodiment and the first embodiment is as follows: in the third embodiment, the non-circuit substrate 1 has a surrounding convex portion 13 disposed on an outer surface thereof for contacting the chip C. Therefore, the contact area between the chip C and the non-circuit substrate 1 can be decreased by using the surrounding convex portion 13 so as to avoid gaps that may be formed between the chip C and the non-circuit substrate 1, so that the chip C can be easily and stably sucked by the non-circuit substrate 1

### Fourth Embodiment

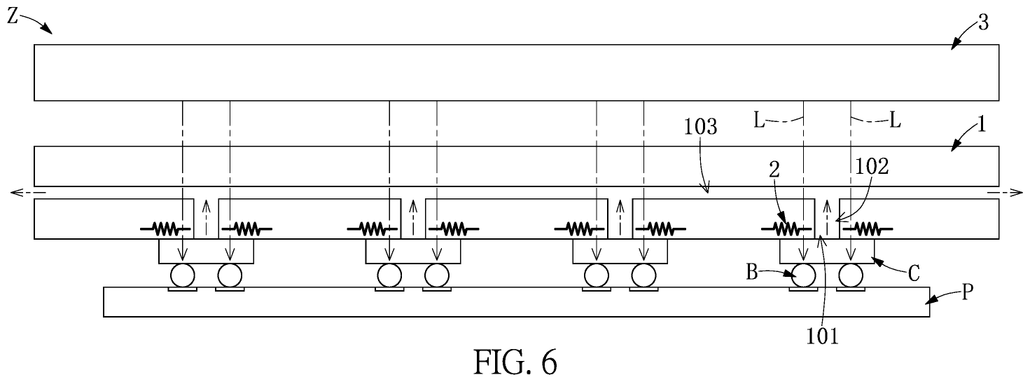

Referring to FIG. 6, a fourth embodiment of the present disclosure provides a chip carrying structure Z having chip-suction function, including a non-circuit substrate 1 and at least one micro heater 2. Comparing FIG. 6 with FIG. 2, the difference between the fourth embodiment and the first embodiment is as follows: in the fourth embodiment, the chip carrying structure Z further includes a laser heating module 3 disposed above the non-circuit substrate 1 for projecting a laser light beam L onto the at least one solder ball B. More particularly, before each of the micro heaters 2 heats the corresponding chip C, the laser light beam L generated by the laser heating module 3 can be projected toward the solder ball B. For example, the laser light beam L passes through the n-type conductive layer, the light-emitting layer and the p-type conductive layer of the chip C, and is projected onto the solder ball B that is arranged on the circuit substrate P. By preheating the solder ball B through the laser heating module 3, and heating the solder ball B by the micro heater 2, the voltage supplied to the micro heater 2 can be greatly reduced. That is to say, preheating the solder ball B through the laser light beam L can greatly reduce the temperature preset value of the micro heater 2 that is to be instantaneously increased. For example, in a situation where only the heater 2 is heated by the micro heater 2, the temperature at which the micro heater 2 is instantaneously raised is preset to 700 degrees, and in a situation where the laser light beam L preheats the solder ball B, the temperature at which the micro heater 2 is instantaneously raised is preset to 400 degrees or lower. However, the aforementioned description for the laser heating module 3 of the forth embodiment is merely an example and is not meant to limit the scope of the present disclosure.

### Fifth Embodiment

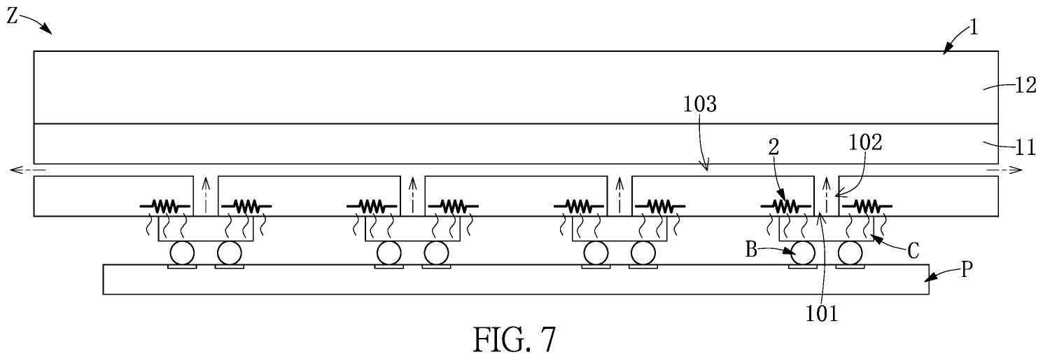

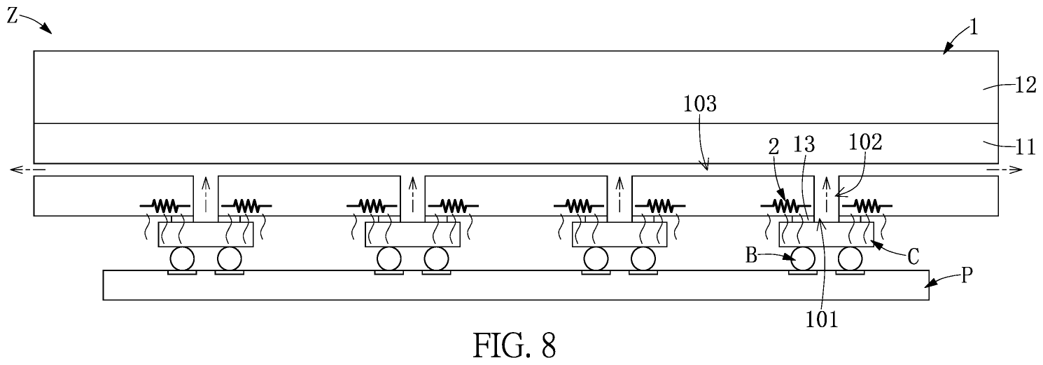

Referring to FIG. 7, a fifth embodiment of the present disclosure provides a chip carrying structure Z having chip-suction function, including a non-circuit substrate 1 and at least one micro heater 2. Comparing FIG. 7 with FIG. 2, the difference between the fifth embodiment and the first embodiment is as follows: in the fifth embodiment, the non-circuit substrate 1 includes a first substrate 11 and a second substrate 12 connected with the first substrate 11. In addition, the openings 101 are formed on the first substrate 11, and each of the air extraction channels 102 passes through the first substrate 11 and the second substrate 12. For example, the hardness of the first substrate 11 is greater than, equal to or smaller than the hardness of the second substrate 12. However, the aforementioned description for the non-circuit substrate 1 of the fifth embodiment is merely an example and is not meant to limit the scope of the present disclosure.

### Sixth Embodiment

Referring to FIG. 8, a sixth embodiment of the present disclosure provides a chip carrying structure Z having chip-suction function, including a non-circuit substrate 1 and at least one micro heater 2. Comparing FIG. 8 with FIG. 7, the difference between the sixth embodiment and the fifth embodiment is as follows: in the sixth embodiment, the first substrate 11 of the non-circuit substrate 1 has a surrounding convex portion 13 disposed on an outer surface thereof for contacting the chip C. Therefore, the contact area between the chip C and the first substrate 11 can be decreased by using the surrounding convex portion 13 so as to avoid gaps that may be formed between the chip C and the first substrate 11, so that the chip C can be easily and stably sucked by the first substrate 11 of the non-circuit substrate 1.

### Seventh Embodiment

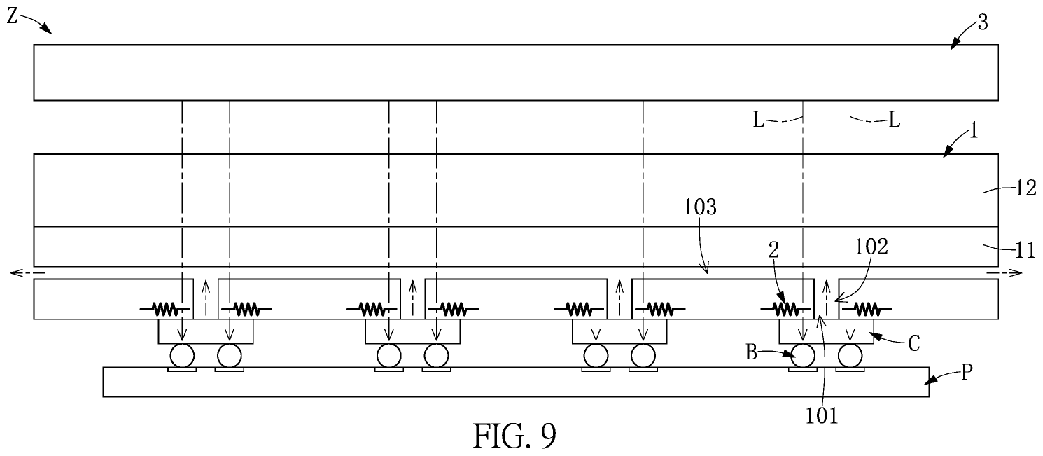

Referring to FIG. 9, a seventh embodiment of the present disclosure provides a chip carrying structure Z having chip-suction function, including a non-circuit substrate 1 and at least one micro heater 2. Comparing FIG. 9 with FIG. 7, the difference between the seventh embodiment and the fifth embodiment is as follows: in the seventh embodiment, the chip carrying structure Z further includes a laser heating module 3 disposed above the non-circuit substrate 1 for projecting a laser light beam L onto the at least one solder ball B. More particularly, before each of the micro heaters 2 heats the corresponding chip C, the laser light beam L generated by the laser heating module 3 can be projected toward the solder ball B. For example, the laser light beam L passes through the n-type conductive layer, the light-emitting layer and the p-type conductive layer of the chip C, and is projected onto the solder ball B that is arranged on the circuit substrate P. By preheating the solder ball B through the laser heating module 3, and heating the solder ball B by the micro heater 2, the voltage supplied to the micro heater 2 can be greatly reduced. That is to say, preheating the solder ball B through the laser light beam L can greatly reduce the temperature preset value of the micro heater 2 that is to be instantaneously increased. For example, in a situation where only the heater 2 is heated by the micro heater 2, the temperature at which the micro heater 2 is instantaneously raised is preset to 700 degrees, and in a situation where the laser light beam L preheats the solder ball B, the temperature at which the micro heater 2 is instantaneously raised is preset to 400 degrees or lower. However, the aforementioned description for the laser heating module 3 of the seventh embodiment is merely an example and is not meant to limit the scope of the present disclosure.

In conclusion, by virtue of “the non-circuit substrate 1 having a plurality of openings 101 and a plurality of air extraction channels 102 respectively communicated with the openings 101” and “the micro heater 2 being carried by the non-circuit substrate 1”, each of the openings 101 of the non-circuit substrate 1 can contact and suck a chip C, and the micro heater 2 can heat at least one solder ball B that is contacted by the at least one chip C.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A chip carrying structure having chip-suction function, comprising:
a non-circuit substrate having a plurality of openings and a plurality of air extraction channels respectively communicated with the openings; and
a plurality of micro heaters disposed on the non-circuit substrate and carried by the non-circuit substrate;
wherein each of the openings of the non-circuit substrate contacts and suctions one of a plurality of chips, and no adhesive layer is disposed between the non-circuit substrate and the chip.

2. The chip carrying structure according to claim 1, wherein the non-circuit substrate is a single substrate or a composite substrate, the chips are correspondingly disposed under the micro heaters, and the chip is an IC chip or an LED chip; wherein each of the micro heaters heats at least one of the chips so as to bond the at least one of the chips on a circuit substrate through a solder ball.

3. The chip carrying structure according to claim 2, wherein the non-circuit substrate includes a first substrate and a second substrate connected with the first substrate, the hardness of the first substrate is greater than, equal to or smaller than the hardness of the second substrate, the openings are formed on the first substrate, and each of the air extraction channels passes through the first substrate and the second substrate; wherein the first substrate has a surrounding convex portion disposed on an outer surface thereof for contacting the chip, and the air extraction channels are communicated with each other.

4. The chip carrying structure according to claim 1, wherein the non-circuit substrate has a surrounding convex portion disposed on an outer surface thereof for contacting the chip, and the air extraction channels are communicated with each other.

5. A chip carrying structure having chip-suction function, comprising:
a non-circuit substrate for carrying at least one chip; and
at least one micro heater carried by the non-circuit substrate for heating at least one solder ball that is contacted by the at least one chip;
wherein the non-circuit substrate has a plurality of openings and a plurality of air extraction channels respectively communicated with the openings.

6. The chip carrying structure according to claim 5, wherein the at least one chip is bonded on a circuit substrate through the at least one solder ball, so that the at least one chip is attached and carried by the circuit substrate to be separate from the non-circuit substrate.

7. The chip carrying structure according to claim 5, wherein the non-circuit substrate is a single substrate or a composite substrate, the at least one chip is correspondingly disposed under the at least one micro heater, and the at least one chip is an IC chip or an LED chip; wherein the at least one micro heater heats the at least one chip so as to bond the at least one chip on a circuit substrate through the at least one solder ball.

8. The chip carrying structure according to claim 7, wherein the non-circuit substrate includes a first substrate and a second substrate connected with the first substrate, the hardness of the first substrate is greater than, equal to or smaller than the hardness of the second substrate, the openings are formed on the first substrate, and each of the air extraction channels passes through the first substrate and the second substrate; wherein the first substrate has a surrounding convex portion disposed on an outer surface thereof for contacting the at least one chip, and the air extraction channels are communicated with each other.

9. The chip carrying structure according to claim 5, wherein the non-circuit substrate has a surrounding convex portion disposed on an outer surface thereof for contacting the at least one chip, and the air extraction channels are communicated with each other.

10. The chip carrying structure according to claim 5, further comprising: a laser heating module disposed above the non-circuit substrate for projecting a laser light beam onto the at least one solder ball.
